(19) United States
(12) Patent Application Publication
(10) Pub. No.: US 2008/0123328 A1
(43) Pub. Date: May 29, 2008

(54) Solar-powered illuminator

(75) Inventors: Li-Hung Lai, Taichung City (TW); Kun-Fang Huang, Taichung (TW); Wen-Sheng Hsieh, Taichung (TW); Li-Wen Lai, Hsinchu Hsien (TW)

Correspondence Address: BACON & THOMAS, PLLC, 625 SLATERS LANE, FOURTH FLOOR, ALEXANDRIA, VA, 22314, US

(73) Assignees: HIGHER WAY ELECTRONIC CO., LTD., Taichung City (TW); Millennium Communication Co., Ltd, Hsinchu Hsien (TW)

(21) Appl. No.: 11/605,246

(22) Filed: Nov. 29, 2006

(51) Int. Cl. F21L 4/00; H01L 33/00

(52) U.S. Cl. 362/183; 257/81; 257/E33.077

(57) ABSTRACT

A solar-powered illuminator, which includes an integrated light receiving and emitting device having a solar chip and a LED chip, a rechargeable battery and an Application-Specific Integrated Circuit (ASIC), is provided. A transparent encapsulant of the integrated light receiving and emitting device focuses the incident sunlight on the solar chip to generate a first voltage. The rechargeable battery is electrically connected to the integrated light receiving and emitting device and is charged by the solar chip in the first voltage. The ASIC is electrically connected to the rechargeable battery and the light receiving and emitting device, and it steps up the first voltage into a second voltage and drives the LED chip to emit light via the discharge of the rechargeable battery in the second voltage. Consequently, the solar-powered illuminator has the advantages of small size, compactness, simple integration, easy installation and cost-effectiveness.

### BACKGROUND OF THE INVENTION

1. Field of the Invention

The present invention relates to a solar-powered illuminator, and more particularly, to the solar-powered illuminator using an integrated light receiving and illuminating device.

2. Description of the Prior Art

Solid-state lighting source, such as the light emitting diode (LED), becomes more and more cost-effective as the technology advances. LED has the advantages of small volume, electricity saving, long life, glass free and toxic-gases free . . . etc. There are versatile LEDs, which includes red LEDs, blue LEDs, green LEDs and white LEDs, can be applied in many lighting application fields according to different usages, such as decoration, indication, display and illumination.

On the other hand, solar cells are increasingly used as the clean energy sources because the solar energy is free and never used out, and the oil is getting more and more shorted and expensive. The solar chip of the light-focus type, which is usually compound-based, such as GaAs-based, InGaAs-based, CdTe-based, AlGaAs-based or Culn(Ga)Se2-based, has the advantage of high photo-voltaic efficiency. Therefore, it is getting popular and is commonly used nowadays.

A solar-powered illuminator using the LED as the light-emitting device in the nighttime is widely used for many applications, such as the streetlamp, the warning sign and the indication sign for the road application. Besides, it is also utilized as the outdoor decoration lamp, the courtyard lamp, the garden lamp and the advertisement lamp . . . etc. Conventionally, the solar-powered illuminator normally includes a LED chip, a solar chip, a rechargeable battery and a controller. The solar chip receives the sunlight during the daytime and converts the solar energy into the electrical energy to store in the rechargeable battery. During the nighttime, the controller controls the rechargeable battery to discharge the stored electrical energy to drive the LED chip to emit light. Accordingly, the merit of the conventional solar-powered illuminator is that it does not need to hard-wire a connection with an external electrical system or recharge the rechargeable battery by using an external electrical source. The hard-wiring is difficult, inconvenient and expensive, and the recharge process is time-consuming, messy, troublesome and expensive.

However, the solar chip and the LED chip are packaged separately, so the conventional solar-powered illuminator is complex for integration, bulky, and expensive.

Furthermore, the conventional solar-powered illuminator often contains a sensor to detect the intensity of the incident sunlight to provide the controller for deciding when to drive the LED chip to emit light. Normally, the detected sunlight intensity is strong and the LED chip does not emit light during the daytime, and the detected sunlight intensity is weak and the LED chip emits light during the nighttime. Nevertheless, the additional sensor needs some hard-wiring with other components, so it makes the integration process of the conventional solar-powered illuminator more complex. Accordingly, the conventional solar-powered illuminator with a sensor is even more bulky, expensive and inconvenient to install.

### SUMMARY OF THE INVENTION

In order to solve the aforementioned problem of being complex, bulky, and expensive for the conventional solar-powered illuminator that the solar chip and the LED chip are packaged separately, one object of the present invention is to provide a solar-powered illuminator utilizing an integrated light receiving and emitting device.

One object of the present invention is to provide a solar-powered illuminator, which does not need to hard-wire a connection with an external electrical system or recharge a rechargeable battery by using an external electrical source.

One object of the present invention is to provide a solar-powered illuminator utilizing an integrated light receiving and emitting device, which has the advantages of small size, compactness, simple integration, easy installation and cost-effectiveness.

Consequently, the solar-powered illuminator of the present invention is very suitable for versatile outdoor applications, such as the decoration lamp, the courtyard lamp, the garden lamp and the advertisement lamp . . . etc. Furthermore, it can also be applied for the road applications, such as the streetlamp, the warning sign and the indication sign.

To achieve the objects mentioned above, one embodiment of the present invention is to provide an integrated light receiving and emitting device, which includes: a solar chip set on a carrier-base; a LED chip set on the carrier-base; a transparent encapsulant covering the LED chip and the solar chip; and a conductive structure partially exposed to the transparent encapsulant, wherein the solar chip provides the LED chip with power via the conductive structure.

To achieve the objects mentioned above, one embodiment of the present invention is to provide a solar-powered illuminator, which includes: an integrated light receiving and emitting device having a solar chip and a LED chip; a rechargeable battery; and an Application-Specific Integrated Circuit (ASIC). A transparent encapsulant of the integrated light receiving and emitting device focuses the incident sunlight on the solar chip to generate a first voltage. The rechargeable battery is electrically connected to the integrated light receiving and emitting device and is charged by the solar chip in the first voltage. The ASIC is electrically connected to the rechargeable battery and the light receiving and emitting device, and it steps up the first voltage into a second voltage and drives the LED chip to emit light via the discharge of the rechargeable battery in the second voltage. Besides, the ASIC may drive the LED chip to emit light when the first voltage is lower than a predetermined threshold voltage since the detected sunlight intensity is weak during the nighttime.

Other objects, technical contents, features and advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a cross-sectional view schematic diagram to illustrate the structure of an integrated light receiving and emitting device according to one embodiment of the present invention;

FIG. 2 is a cross-sectional view schematic diagram to illustrate the structure of an integrated light receiving and emitting device according to one preferred embodiment of the present invention;

FIG. 3 is a cross-sectional view schematic diagram to illustrate the structure of an integrated light receiving and emitting device according to one preferred embodiment of the present invention;

FIG. 4 is a cross-sectional view schematic diagram to illustrate the structure of an integrated light receiving and emitting device according to one preferred embodiment of the present invention; and

FIG. 5 is a schematic block diagram to illustrate the structure of a solar-powered illuminator according to one embodiment of the present invention.

### DESCRIPTION OF THE PREFERRED EMBODIMENT

The detailed explanation of the present invention is described as following. The described preferred embodiments are presented for purposes of illustrations and description, and they are not intended to limit the scope of the present invention.

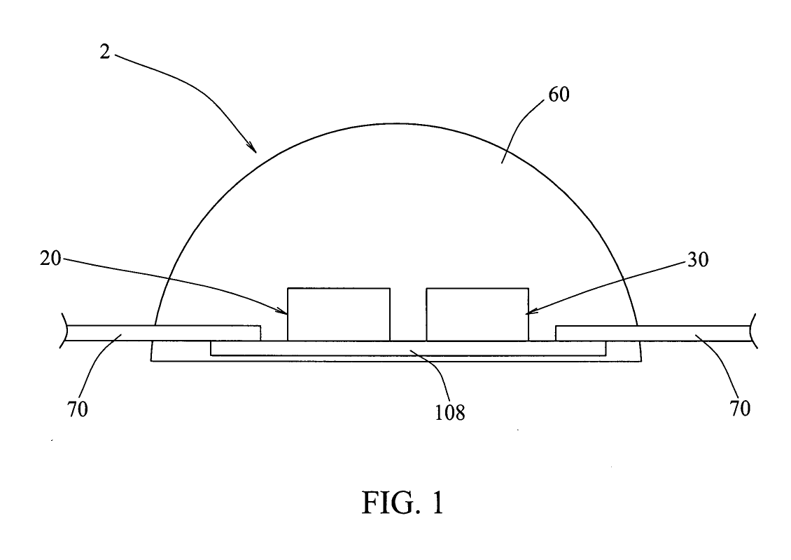

FIG. 1 is a cross-sectional view schematic diagram to illustrate the structure of an integrated light receiving and emitting device 2 according to an embodiment of the present invention, the integrated light receiving and emitting device 2 in SMD (Surface Mount Device) package type includes: a solar chip 20 and a LED chip 30 set on the carrier-base 108; a transparent encapsulant 60 covering the LED chip 30 and the solar chip 20; and a conductive structure 70 partially exposed to the transparent encapsulant 60, wherein the solar chip 20 provides the LED chip 30 with power via the carrier-base 108 and the conductive structure 70.

In one preferred embodiment, the transparent encapsulant 60 has a curved surface but does not limit to, and a focus thereof is on the solar chip 20; and the transparent encapsulant 60 may be composed of epoxy molding compound or glass which is configured for anti-reflecting incident light and protecting the solar chip 20 and the LED chip 30. The solar chip 20 may be the compound-based solar chip, such as GaAs-based, InGaAs-based, CdTe-based, AlGaAs-based, Culn(Ga)Se₂-based solar chip or their combinations. And, the LED chip 30 may be chosen from many types, such as an LED array, a red LED chip, a blue LED chip, a green LED chip and a white LED chip.

Therefore, one feature of the present invention is that both the solar chip 20 and the LED chip 30 are packaged together in the integrated light receiving and emitting device 2. Comparing to the conventional solar-powered illuminator using the LED as the illuminating device, which the solar chip and the LED chip are packaged separately, the integrated light receiving and emitting device 2 according to the present invention has the advantages of simple integration, compactness and cost-effectiveness.

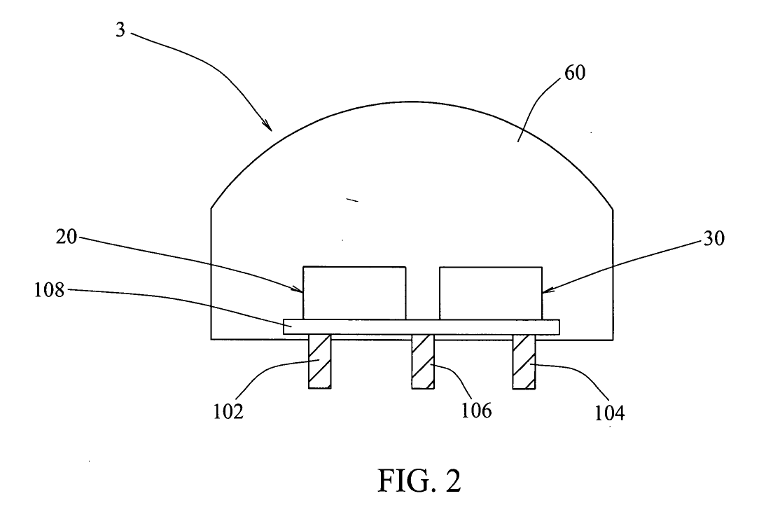

FIG. 2 is a cross-sectional view schematic diagram to illustrate the structure of an integrated light receiving and emitting device 3 according to a preferred embodiment of the present invention, the conductive structure includes a first positive-pole metal lead 102, a second positive-pole metal lead 104 and a common-pole metal lead 106. Wherein the solar chip 20 is used to convert the solar energy into the electrical energy through generating a first voltage between the first positive-pole metal lead 102 and the common-pole metal lead 106 when receiving the incident sunlight, and the transparent encapsulant 60 may be used to focus and anti-reflect the incident sunlight on the solar chip 20. The LED chip 30 is used to emit light through applying a second voltage between the second positive-pole metal lead 104 and the common-pole metal lead 106.

In embodiments of the present invention, there are several different kinds of LED chips: one type is that the P-electrode of the LED chip is set on the top surface, and the N-electrode of the LED chip is set on the bottom surface; the other type is that both the P-electrode and the N-electrode of the LED chip are set on the top surface. The corresponding package structures for them are described in the following embodiments.

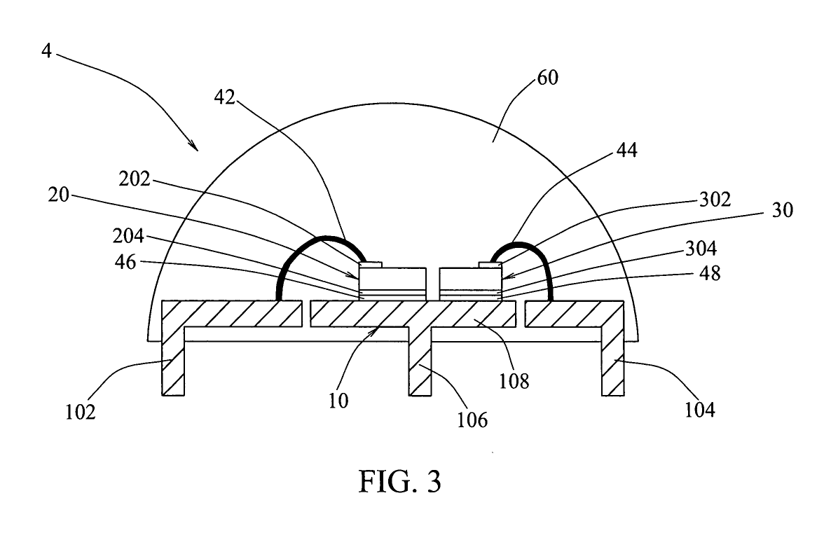

FIG. 3 is a cross-sectional view schematic diagram to illustrate the structure of an integrated light receiving and emitting device 4 according to a preferred embodiment of the present invention. A first P-electrode 202 is set on the top surface of the solar chip 20, and a first N-electrode 204 is set on the bottom surface of the solar chip 20. A second P-electrode 302 is on the top surface of the LED chip 30, and the second N-electrode 304 is set on the bottom surface of the LED chip 30. And, the integrated light receiving and emitting device 4 has a lead frame 10, which includes the carrier-base 108, the first positive-pole metal lead 102, the common-pole metal lead 106 and the second positive-pole metal lead 104.

Please continuously refer to FIG. 3; in one preferred embodiment, the first P-electrode 202 is electrically connected to the first positive-pole metal lead 102 via a first metal wire 42 bonding to the lead frame 10, and the second P-electrode 302 is electrically connected to the second positive-pole metal lead 104 via a second metal wire 44 bonding to the lead frame 10. A first conductive paste 46 is set between the first N-electrode 204 and the carrier-base 108 to adhere and fix the solar chip 20 on the lead frame 10, and electrically connect the first N-electrode 204 and the common-pole metal lead 106; and a second conductive paste 48 is set between the second N-electrode 304 and the carrier-base 108 to adhere and fix the LED chip 30 on the lead frame 10, and electrically connect the second N-electrode 304 and the common-pole metal lead 106. The first conductive paste 46 and the second conductive paste 48 may be silver pastes.

The functions and the related setups of the solar chip 20, the LED chip 30, the first positive-pole metal lead 102, the common-pole metal lead 106, the second positive-pole metal lead 104, and the transparent encapsulant 60 in FIG. 3 have been described in the preceding paragraphs for FIG. 2, so they are not further described herein.

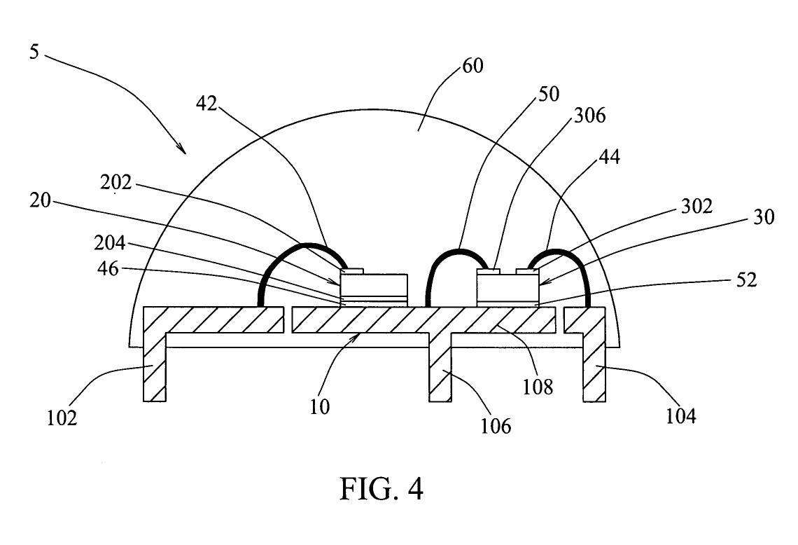

FIG. 4 is a cross-sectional view schematic diagram to illustrate the structure of an integrated light receiving and emitting device 5 according to another preferred embodiment of the present invention, the differences between the structures illustrated in FIG. 4 and FIG. 3 are described as follows. The second N-electrode 306 is set besides the second P-electrode 302 on the top surface of the LED chip 30, and the second N-electrode 306 is electrically connected to the common-pole metal lead 106 via a third metal wire 50 bonding to the lead frame 10. An insulated epoxy 52 is set between the LED chip 30 and the carrier-base 108 to adhere and fix the LED chip 30 on the lead frame 10.

Accordingly, one feature of the present invention is that the P-electrode and the N-electrode of the LED chip may be set on the same side or the opposite side. The integrated light receiving and emitting device of the present invention may include a lead frame to carry the solar chip and LED chip, and the solar chip may provide the LED chip with power via the lead frame.

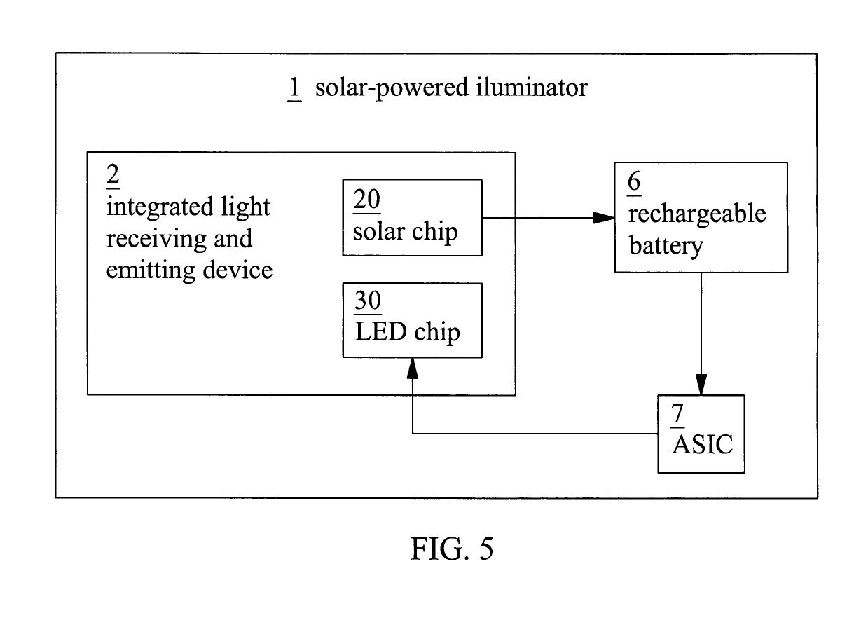

FIG. 5 is a schematic block diagram to illustrate the structure of a solar-powered illuminator 1 according to an embodiment of the present invention, please refer to FIG. 1 simultaneously. The solar-powered illuminator 1 includes: an integrated light receiving and emitting device 2 as described for FIG. 1, wherein the transparent encapsulant 60 focuses the incident sunlight on the solar chip 20 to generate a first voltage; a rechargeable battery 6 electrically connected to the conductive structure 70 and charged by the solar chip 20 in the first voltage; and an ASIC 7 electrically connected to the rechargeable battery to step up the first voltage into a second voltage and electrically connected to the conductive structure 70 to drive the LED chip 30 to emit light via the discharge of the rechargeable battery 6 in the second voltage.

In one preferred embodiment, the second voltage is higher than the first voltage. Furthermore, the second voltage is not lower than 3 V, and the first voltage is higher than 1.2 V. And, the ASIC 7 may drive the LED chip 30 to emit light when the first voltage generated by the solar chip 20 and detected by the ASIC 7 is lower than a predetermined threshold voltage. Normally, during the daytime, the intensity of the incident sunlight is strong and the first voltage generated by the solar chip 20 is higher than the predetermined threshold voltage, so the LED chip does not emit light. On the contrary, during the nighttime, the intensity of the incident sunlight is weak and the first voltage generated by the solar chip 20 is lower than the predetermined threshold voltage, so the LED chip emits light.

To summarize, the solar-powered illuminator of the present invention utilizes the integrated light receiving and emitting device provided by the present invention, so it has the advantages of simple integration, compactness and cost-effectiveness. It does not need to hard-wire a connection with an external electrical system or recharge a rechargeable battery by using an external electrical source. Besides, the solar-powered illuminator of the present invention does not need an additional sensor for deciding when to drive the LED chip to emit light. It makes the solar-powered illuminator of the present invention even more simple, small, cheap and easy to install in comparison with the conventional solar-powered illuminator.

Consequently, the solar-powered illuminator of the present invention is very suitable for versatile outdoor applications, such as the decoration lamp, the courtyard lamp, the garden lamp and the advertisement lamp . . . etc. Furthermore, it can also be applied for the road applications, such as the streetlamp, the warning sign and the indication sign.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. An integrated light receiving and emitting device, comprising:
a solar chip set on a carrier-base;
a Light Emitting Diode (LED) chip set on said carrier-base;
a transparent encapsulant covering said LED chip and said solar chip; and
a conductive structure partially exposed to said transparent encapsulant, wherein said solar chip provides said LED chip with power via at least one of said carrier-base and said conductive structure.

2. The integrated light receiving and emitting device according to claim 1, wherein said transparent encapsulant has a curved surface.

3. The integrated light receiving and emitting device according to claim 1, wherein a focus of said transparent encapsulant is on said solar chip.

4. The integrated light receiving and emitting device according to claim 1, wherein said transparent encapsulant is composed of epoxy molding compound or glass.

5. The integrated light receiving and emitting device according to claim 1, wherein said LED chip is an LED array.

6. The integrated light receiving and emitting device according to claim 1, wherein said LED chip is selected from the group consisting of a red LED chip, a blue LED chip, a green LED chip and a white LED chip.

7. The integrated light receiving and emitting device according to claim 1, wherein said solar chip is compound-based, which comprises GaAs-based, InGaAs-based, CdTe-based, AlGaAs-based, Culn(Ga)Se₂-based solar chip or a combination thereof.

8. The integrated light receiving and emitting device according to claim 1, wherein said solar chip comprises a first P-electrode and a first N-electrode, said LED chip comprises a second P-electrode and a second N-electrode, said conductive structure comprises a first positive-pole metal lead, a common-pole metal lead and a second positive-pole metal lead; and wherein said first positive-pole metal lead, said common-pole metal lead and said second positive-pole metal lead are electrically isolated for each other, said first N-electrode and said second N-electrode are electrically connected to said common-pole metal lead, said first P-electrode is electrically connected to said first positive-pole metal lead, and said second P-electrode is electrically connected to said second positive-pole metal lead.

9. The integrated light receiving and emitting device according to claim 8, wherein said integrated light receiving and emitting device comprises a lead frame having said carrier-base, said first positive-pole metal lead, said common-pole metal lead and said second positive-pole metal lead.

10. The integrated light receiving and emitting device according to claim 9, wherein said first P-electrode is set on a top surface of said solar chip and said first N-electrode is set on a bottom surface of said solar chip, said second P-electrode is set on a top surface of said LED chip, and said second N-electrode is set on a bottom surface of said LED chip.

11. The integrated light receiving and emitting device according to claim 10, wherein said first P-electrode is electrically connected to said first positive-pole metal lead via a first metal wire bonding to said lead frame, said second P-electrode is electrically connected to said second positive-pole metal lead via a second metal wire bonding to said lead frame, a first conductive paste is set between said first N-electrode and said carrier-base to adhere and fix said solar chip on said lead frame and electrically connect said first N-electrode and said common-pole metal lead, and a second conductive paste is set between said second N-electrode and said carrier-base to adhere and fix said LED chip on said lead frame and electrically connect said second N-electrode and said common-pole metal lead.

12. The integrated light receiving and emitting device according to claim 11, wherein said first conductive paste and said second conductive paste are silver pastes.

13. The integrated light receiving and emitting device according to claim 9, wherein said first P-electrode is set on a top surface of said solar chip and said first N-electrode is set on a bottom surface of said solar chip, said second P-electrode is set on a top surface of said LED chip, and said second N-electrode is set besides said second P-electrode on said top surface of said LED chip.

14. The integrated light receiving and emitting device according to claim 13, wherein said first P-electrode is electrically connected to said first positive-pole metal lead via a first metal wire bonding to said lead frame, said second P-electrode is electrically connected to said second positive-pole metal lead via a second metal wire bonding to said lead frame, a conductive paste is set between said first N-electrode and said carrier-base to adhere and fix said solar chip on said lead frame and electrically connect said first N-electrode and said common-pole metal lead, said second N-electrode is electrically connected to said common-pole metal lead via a third metal wire bonding to said lead frame, and an insulated epoxy is set between said LED chip and said carrier-base to adhere and fix said LED chip on said lead frame.

15. The integrated light receiving and emitting device according to claim 14, wherein said conductive paste is a silver paste.

16. A solar-powered illuminator applying said integrated light receiving and emitting device according to claim 1, comprising:
said integrated light receiving and emitting device, wherein said transparent encapsulant focuses incident sunlight on said solar chip to generate a first voltage;
a rechargeable battery electrically connected to said conductive structure and charged by said solar chip in said first voltage; and
an Application-Specific Integrated Circuit (ASIC) electrically connected to said rechargeable battery to step up said first voltage to a second voltage and electrically connected to said conductive structure to drive said LED chip to emit light via discharge of said rechargeable battery in said second voltage.

17. The solar-powered illuminator according to claim 16, wherein said ASIC drives said LED chip to emit light when said first voltage detected by said ASIC is lower than a predetermined threshold voltage.

18. The solar-powered illuminator according to claim 16, wherein said second voltage is higher than said first voltage.

19. The solar-powered illuminator according to claim 18, wherein said second voltage is not lower than 3 V, and said first voltage is higher than 1.2 V.
